(19) United States
(12) Patent Application Publication
(10) Pub. No.: US 2025/0176210 A1
(43) Pub. Date: May 29, 2025

(54) SEMICONDUCTOR DEVICE AND FABRICATION METHOD THEREOF

(71) Applicant: Vanguard International Semiconductor Corporation, Hsinchu (TW)

(72) Inventors: Wen-Shan Lee, Hsinchu City (TW); Chung-Yeh Lee, Hsinchu County (TW); Fu-Hsin Chen, Hsinchu County (TW)

(73) Assignee: Vanguard International Semiconductor Corporation, Hsinchu (TW)

(21) Appl. No.: 18/518,618

(22) Filed: Nov. 24, 2023

(51) Int. Cl. H01L 29/78; H01L 29/06; H01L 29/40; H01L 29/417; H01L 29/66

(52) U.S. Cl. CPC H10D 30/668; H10D 30/0297; H10D 62/107; H10D 64/01; H10D 64/252

(57) ABSTRACT

A semiconductor device includes a substrate having a first surface and a second surface. A gate pad and a source pad are laterally separated from each other and both disposed on the first surface of the substrate. A drain region is disposed on the second surface of the substrate. A first trench and a second trench are disposed in the substrate and directly below the gate pad and the source pad, respectively. A conductive portion fills the first trench. A dielectric liner is disposed in the first trench and surrounds the conductive portion. A first doped region is located on two sides of the first trench. A gate electrode fills the second trench. A gate dielectric layer is disposed in the second trench and surrounds the gate electrode. A source region is located on two sides of the second trench.

### BACKGROUND OF THE INVENTION

### 1. Field of the Invention

The present disclosure relates generally to semiconductor technology, and more particularly to a semiconductor device including trench power transistors and a fabrication method thereof.

### 2. Description of the Prior Art

Power transistors are usually used in power electronic systems as power switches, converters and other power components. Power transistors are typically operated under high voltage and high current. Power metal-Oxide-semiconductor field-effect-transistor (power MOSFET) are common power transistors, which includes a horizontal structure such as a laterally-diffused metal-oxide-semiconductor (LDMOS) field-effect-transistor (FET), and a vertical structure such as a planar gate MOSFET or a trench gate MOSFET. In the trench gate MOSFET, a gate is disposed in a trench. Compared with the planar gate MOSFET, the trench gate MOSFET has the advantage of reducing the size of the component unit. However, the conventional trench gate MOSFETs still cannot fully satisfy various requirements, such as reducing the on-state resistance (Ron) and reducing various parasitic capacitances.

### SUMMARY OF THE INVENTION

In view of this, the present disclosure provides a semiconductor device and a fabrication method thereof, where multiple trenches are disposed directly below a gate pad. A dielectric liner and a conductive portion are disposed in the trench. Moreover, a doped region is disposed on two sides of the trench. The number of effective trench power transistors is increased directly below the gate pad, thereby reducing the specific on-resistance (Ron, sp) of the semiconductor device. Moreover, a thick oxide layer is disposed at the bottom of the trench, thereby reducing the gate-to-drain capacitance (Cgd) beneath the gate pad. Furthermore, a silicide layer is disposed on the doped region located on the sides of the trench by using a self-aligned contact process, thereby reducing the cell pitch of the trench power transistors, which is beneficial to further reduce the specific on-resistance of the semiconductor device.

According to an embodiment of the present disclosure, a semiconductor device is provided and includes a substrate, a gate pad, a source pad, a drain region, a first trench, a conductive portion, a dielectric liner, a first doped region, a second trench, a gate electrode, a gate dielectric layer and a source region. The substrate has a first surface and a second surface. The gate pad and the source pad are laterally separated from each other and both disposed on the first surface of the substrate. The drain region is disposed on the second surface of the substrate. The first trench is disposed in the substrate and directly below the gate pad. The conductive portion fills up the first trench. The dielectric liner is disposed in the first trench and surrounds the conductive portion. The first doped region is located on two sides of the first trench. The second trench is disposed in the substrate and directly below the source pad. The gate electrode fills up the second trench. The gate dielectric layer is disposed in the second trench and surrounds the gate electrode. The source region is located on two sides of the second trench. The first doped region and the source region have the same conductivity type.

According to an embodiment of the present disclosure, a method of fabricating a semiconductor device is provided and includes the following steps. A substrate is provided and includes forming a drain region and forming an epitaxial layer on the drain region. An ion implantation process is performed on the epitaxial layer to form a first doped region and a source region that both have a first conductivity type. A first trench and a second trench are formed in the epitaxial layer, and abut the first doped region and the source region, respectively. A dielectric liner and a gate dielectric layer are formed in the first trench and the second trench, respectively. A conductive portion and a gate electrode are formed in the first trench and the second trench, respectively, where the dielectric liner surrounds the conductive portion, and the gate dielectric layer surrounds the gate electrode. In addition, a gate pad and a source pad are formed on the epitaxial layer, laterally separated from each other, and directly above the first trench and the second trench, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor device according to an embodiment of the present disclosure.

FIG. 2 is a schematic top view of a gate pad and a source pad in a semiconductor device according to an embodiment of the present disclosure.

FIG. 3, FIG. 4, FIG. 5, FIG. 6, FIG. 7, FIG. 8, FIG. 9 and FIG. 10 are schematic cross-sectional views of some stages of a method of fabricating a semiconductor device according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to a semiconductor device including multiple trench power transistors and a fabrication method thereof. In some embodiments, multiple trenches are disposed directly below a gate pad. A dielectric liner and a conductive portion are disposed in each trench. A doped region is disposed on two sides of each trench. The number of effective trench power transistors is increased directly below the gate pad, thereby reducing the specific on-resistance (Ron, sp) of the semiconductor device. Moreover, the contact area between a source electrode and a drift region is significantly reduced, thereby effectively reducing the drain-to-source capacitance (Cds) of the semiconductor device. In addition, a thick oxide layer is disposed at the bottom of each trench, thereby reducing the gate-to-drain capacitance (Cgd) that is generated by the trench power transistors directly below the gate pad, and reducing the switching loss of the semiconductor device. Furthermore, a silicide layer is disposed on the doped region located on two sides of each trench by using a self-aligned contact process, thereby reducing the cell pitch of the trench power transistors, which is beneficial to reduce the specific on-resistance of the semiconductor device.

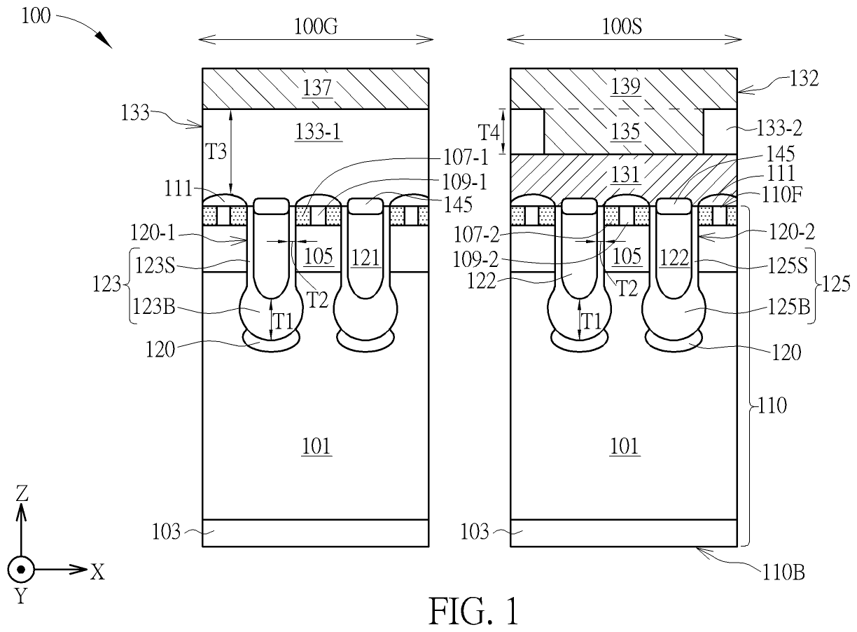

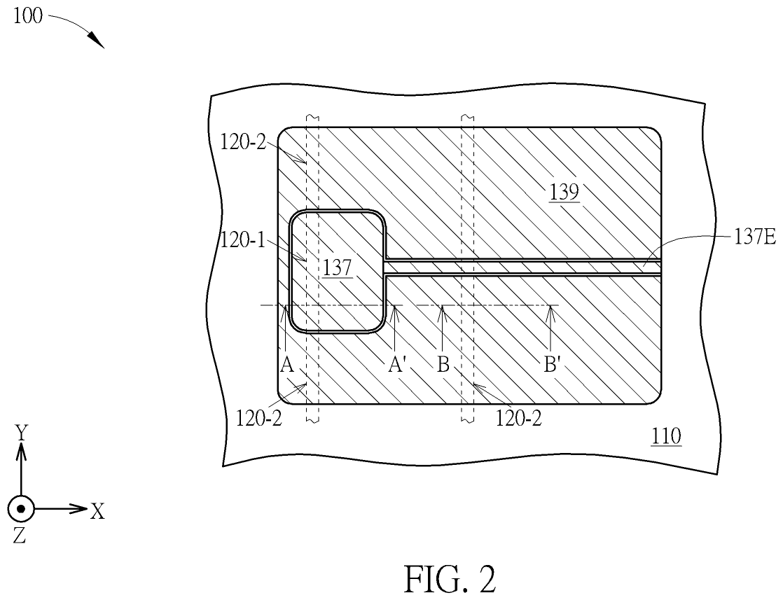

FIG. 1 is a schematic cross-sectional view of a semiconductor device 100 according to an embodiment of the present disclosure. The semiconductor device 100 includes a gate pad region 100G and a source pad region 100S. FIG. 2 is a schematic top view of a gate pad 137 and a source pad 139 in the semiconductor device 100 according to an embodiment of the present disclosure. The gate pad region 100G in FIG. 1 is taken along the section line A-A′ in FIG. 2, and the source pad region 100S in FIG. 1 is taken along the section line B-B′ in FIG. 2. Referring to FIG. 1, the semiconductor device 100 includes a substrate 110 having a first surface 110F (for example, a front surface) opposite to a second surface 110B (for example, a back surface). Moreover, the substrate 110 includes a drain region 103 disposed on the second surface 110B of the substrate. The drain region 103 has a first conductivity type, such as an N-type heavily doped region (N⁺). The substrate 110 further includes an epitaxial layer 101 located on the drain region 103. The epitaxial layer 101 also has the first conductivity type, such as an N-type epitaxial layer. In some embodiments, the drain region 103 is, for example, an N-type heavily doped silicon carbide (N⁺ SiC) substrate, and the epitaxial layer 101 is, for example, an N-type silicon carbide epitaxial layer, but not limited thereto.

Still referring to FIG. 1, the semiconductor device 100 includes a gate pad 137 and a source pad 139 that are both disposed on the first surface 110F of the substrate 110. As shown in FIG. 2, the gate pad 137 and the source pad 139 are disposed on the same plane (for example, the XY plane) and laterally separated from each other. As shown in FIG. 1, the semiconductor device 100 includes multiple first trenches 120-1 disposed in the substrate 110 and located directly below the gate pad 137, and multiple second trenches 120-2 disposed in the substrate 110 and located directly below the source pad 139. As shown in FIG. 2, when viewed from the top, the long axes of both the first trenches 120-1 and the second trenches 120-2 are extended along the same direction (for example, the Y-axis direction). Moreover, one of the first trenches 120-1 directly below the gate pad 137 and one of the second trenches 120-2 directly below the source pad 139 may be aligned with each other and arranged along the same straight line.

As shown in FIG. 1, a dielectric liner 123 is disposed on the sidewalls and the bottom surface of the first trench 120-1 directly below the gate pad 137. The dielectric liner 123 includes a first portion 123S located on the sidewalls of the first trench 120-1 and a second portion 123B located on the bottom surface of the first trench 120-1. The thickness T1 of the second portion 123B in the Z-axis direction is greater than the thickness T2 of the first portion 123S in the X-axis direction. A conductive portion 121 fills up the first trench 120-1, and the dielectric liner 123 surrounds s the conductive portion 121. In addition, a gate dielectric layer 125 is disposed on the sidewalls and the bottom surface of the second trench 120-2 directly below the source pad 139. The gate dielectric layer 125 includes a third portion 125S located on the sidewalls of the second trench 120-2 and a fourth portion 125B located on the bottom surface of the second trench 120-2. The thickness T1 of the fourth part 125B in the Z-axis direction is greater than the thickness T2 of the third portion 125S in the X-axis direction. A gate electrode 122 fills up the second trench 120-2, and the gate dielectric layer 125 surrounds the gate electrode 122.

In addition, the semiconductor device 100 includes a well region 105 disposed in the epitaxial layer 101. The well region 105 has a second conductivity type, such as a P-type well region (p-well). The well region 105 is laterally extended from being directly below the gate pad 137 to be directly below the source pad 139. Moreover, a first doped region 107-1 and a second doped region 109-1 are disposed in the well region 105 directly below the gate pad 137. The first doped region 107-1 has the first conductivity type, such as an N-type heavily doped region (N⁺), and the second doped region 109-1 has the second conductivity type, such as a P-type heavily doped region (P⁺). The first doped region 107-1 abuts two sides of the first trench 120-1. The second doped region 109-1 is located between two first doped regions 107-1 and abuts the two first doped regions 107-1. In addition, a source region 107-2 and a bulk region 109-2 are disposed in the well region 105 directly below the source pad 139. The source region 107-2 has the first conductivity type, such as an N-type heavy Doped region (N⁺), and the bulk region 109-2 has the second conductivity type, such as a P-type heavily doped region (P⁺). The source region 107-2 abuts two sides of the second trench 120-2. The bulk region 109-2 is located between two source regions 107-2 and abuts the two source regions 107-2. Moreover, the semiconductor device 100 includes a silicide layer 111 disposed on the first doped region 107-1, the second doped region 109-1, the source region 107-2 and the bulk region 109-2 by using a self-aligned contact process. The silicide layer 111 is in contact with the top surfaces of the first doped region 107-1, the second doped region 109-1, the source region 107-2 and the bulk region 109-2. The semiconductor device 100 further includes a shield region 102 located in the epitaxial layer 101. The shield region 102 is correspondingly disposed directly below each of the first trenches 120-1 and each of the second trenches 120-2, and surrounds the bottom of each first trench 120-1 and the bottom of each second trench 120-2. The shield region 102 has the second conductivity type, such as a P-type heavily doped region (P⁺). The shield region 102 provides an electric field shielding effect, thereby improving the breakdown voltage of the semiconductor device.

Still referring to FIG. 1, the semiconductor device 100 further includes a first metal layer 131 disposed directly below the source pad 139. The first metal layer 131 is in contact with the silicide layer 111 located directly below the source pad 139. Moreover, the vertical projected area of the first metal layer 131 is not overlapped with the vertical projected area of the gate pad 137. When viewed from the top, the first metal layer 131 is not overlapped with the gate pad 137 on the XY plane. In addition, the semiconductor device 100 includes a dielectric layer 133 covering the first metal layer 131 and the silicide layer 111. A portion 133-1 of the dielectric layer 133 is located directly below the gate pad 137, and another portion 133-2 of the dielectric layer 133 is located directly below the source pad 139. The thickness T3 of the portion 133-1 of the dielectric layer 133 is greater than the thickness T4 of another portion 133-2 of the dielectric layer 133. In one embodiment, a via 135 is disposed in the portion 133-2 of the dielectric layer 133. The gate pad 137 and the source pad 139 are disposed on the dielectric layer 133. The top surface of the gate pad 137 and the top surface of the source pad 139 may be on the same plane. The gate pad 137, the source pad 139 and the via 135 may all be formed from a second metal layer 132. The source pad 139 is electrically connected to the first metal layer 131 through the via 135. In this embodiment, the source pad 139 is electrically connected to the source region 107-2 and the bulk region 109-2 through the first metal layer 131. Moreover, during the fabrication process of the semiconductor device, in the cross-sectional structure, the difference in the height of both the source pad 139 and the via 135 from other portions is reduced by the first metal layer 131, which is beneficial to the process of fabricating the source pad 139 and the via 135.

In one embodiment, the gate electrode 122 and the conductive portion 121 are both electrically coupled to the gate pad 137, thereby having a gate potential. The gate electrode 122 located directly below the source pad 139 is electrically coupled to an extension portion 137E of the gate pad 137 as shown in FIG. 2 through other via and wire (not shown) disposed in the portion 133-2 of the dielectric layer 133 and other vias (not shown) passing through the dielectric layer 145 located above the gate electrode 122, thereby being electrically connected to the gate pad 137. Moreover, the conductive portion 121 located directly below the gate pad 137 is electrically coupled to the gate pad 137 through other via (not shown) passing through the portion 133-1 of the dielectric layer 133 and the dielectric layer 145 located above the conductive portion 121. In addition, the first doped region 107-1 located on two sides of the first trench 120-1 is electrically coupled to the source pad 139 through the silicide layer 111 and other via and wire (not shown) disposed in the portion 133-1 of the dielectric layer 133. The source region 107-2 located on two sides of the second trench 120-2 is electrically coupled to the source pad 139 through the silicide layer 111, the first metal layer 131 and the via 135. In this embodiment, the conductive portion 121 and the dielectric liner 123 in the first trench 120-1 directly below the gate pad 137, and the first doped region 107-1 located on the sides of the first trench 120-1 are used to construct a trench power transistor, so that the number of effective trench power transistors is increased directly below the gate pad 137, thereby reducing the specific on-resistance (Ron, sp) of the semiconductor device 100.

Compared with other semiconductor devices that do not have a trench power transistor directly below the gate pad 137, the specific on-resistance of the semiconductor device 100 in the embodiments of the present disclosure may be reduced by about 5% to about 10%, but not limited thereto. When the ratio of the area of the gate pad 137 to the overall area of a die is higher, the number of effective trench power transistors directly below the gate pad 137 is increased, so that the reduction in the specific on-resistance (Ron, sp) of the semiconductor device 100 is greater. Especially for small-sized dies, the ratio of the area of the gate pad to the overall area of a die is high, so that the effect of reducing the specific on-resistance is more significant. Moreover, in other embodiments, depending on various electrical requirements of the semiconductor device 100, the conductive portion 121 in the first trench 120-1 may be electrically coupled to the potentials other than the gate potential. For example, the conductive portion 121 in the first trench 120-1 may be electrically coupled to a source potential or a ground terminal.

In addition, compared with other semiconductor devices that do not have a trench disposed directly below the gate pads 137, the drain-to-source capacitance (Cds) of the semiconductor device in the embodiments of the present disclosure is effectively reduced by the multiple first trenches 120-1 disposed directly below the gate pads 137. Moreover, in some embodiments of the present disclosure, a thick oxide layer, i.e., the second portion 123B of the dielectric liner 123 is disposed at the bottom of the first trench 120-1 directly below the gate pad 137, thereby reducing the gate-to-drain capacitance (Cgd) produced by arranging the trench power transistors directly below the gate pad 137, and also reducing the switching loss of the semiconductor device 100. Furthermore, in some embodiments of the present disclosure, the silicide layer 111 is disposed on the first doped region 107-1, the second doped region 109-1, the source region 107-2 and the bulk region 109-2 by using a self-aligned contact process, thereby reducing the cell pitch of the trench power transistors, which is beneficial to reduce the specific on-resistance (Ron, sp) of the semiconductor device 100.

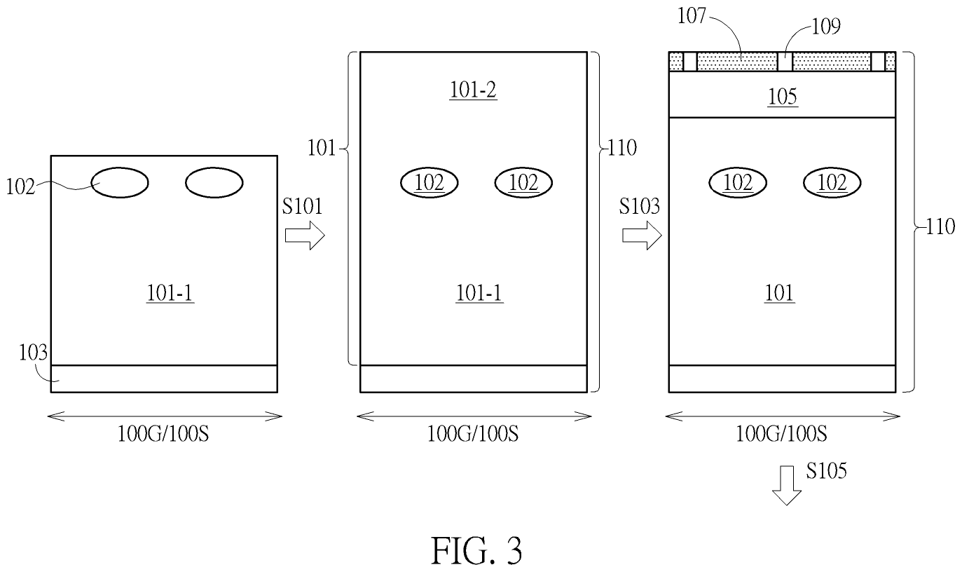

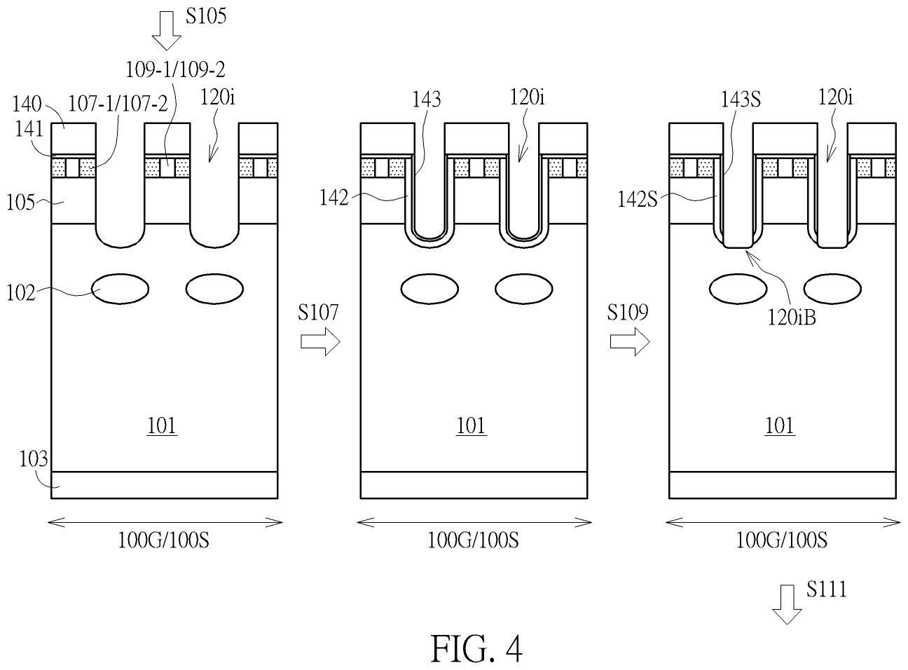

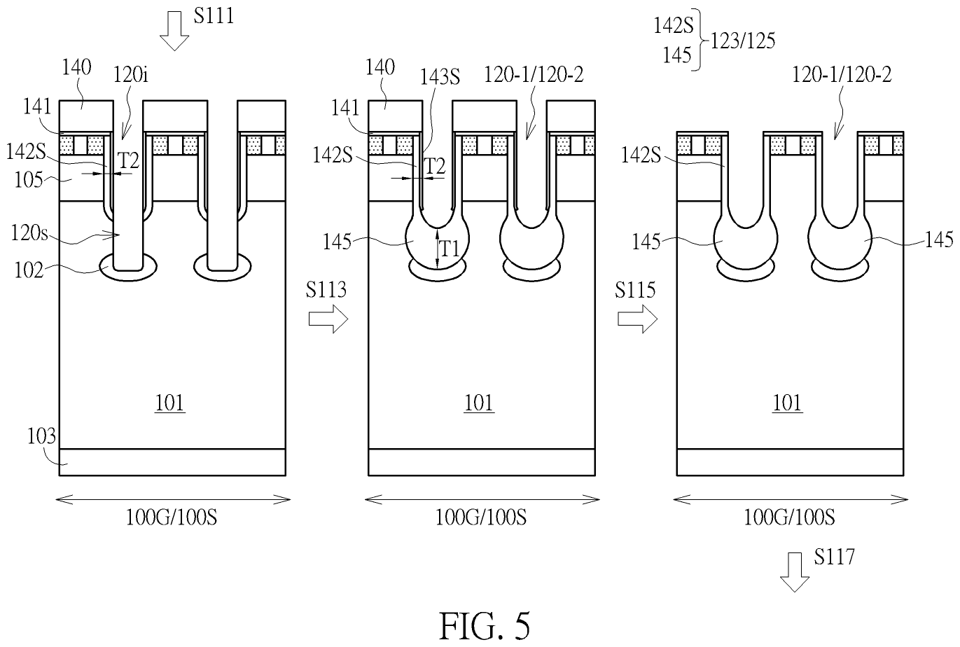

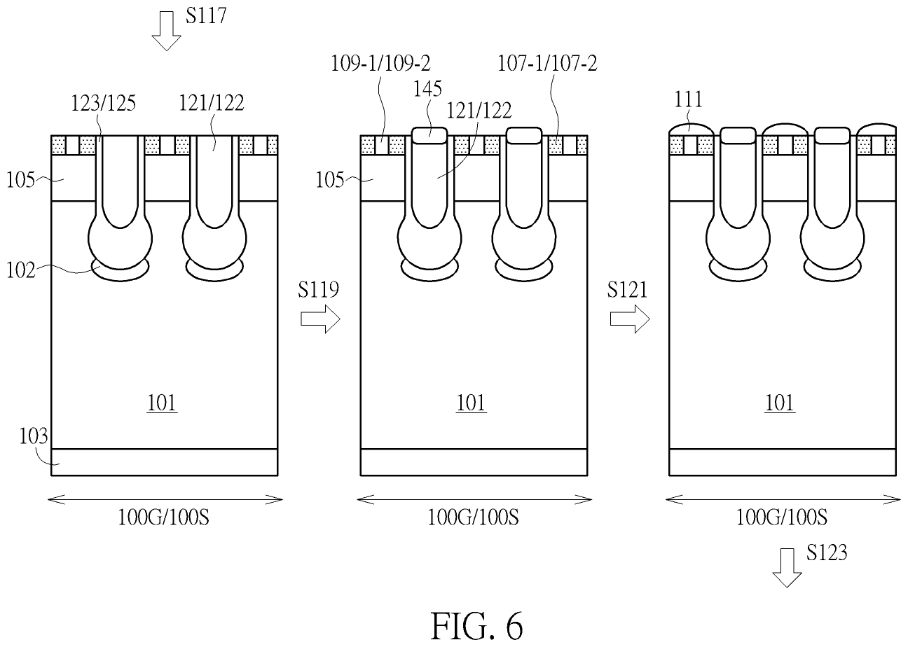

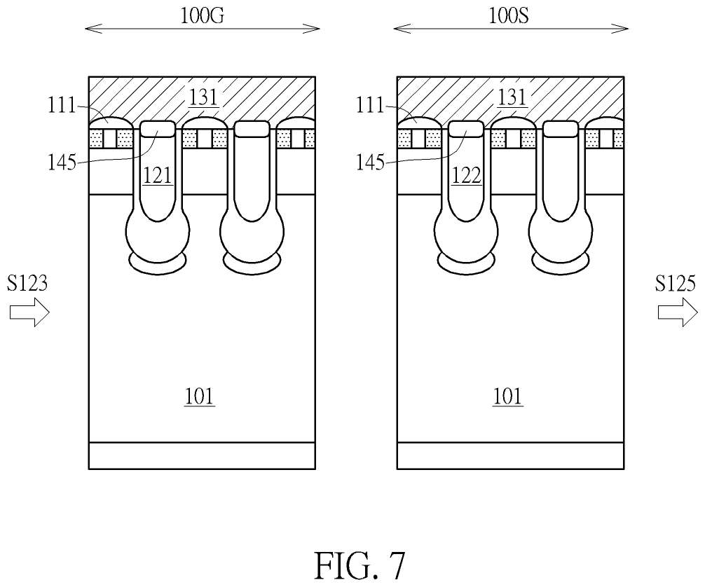

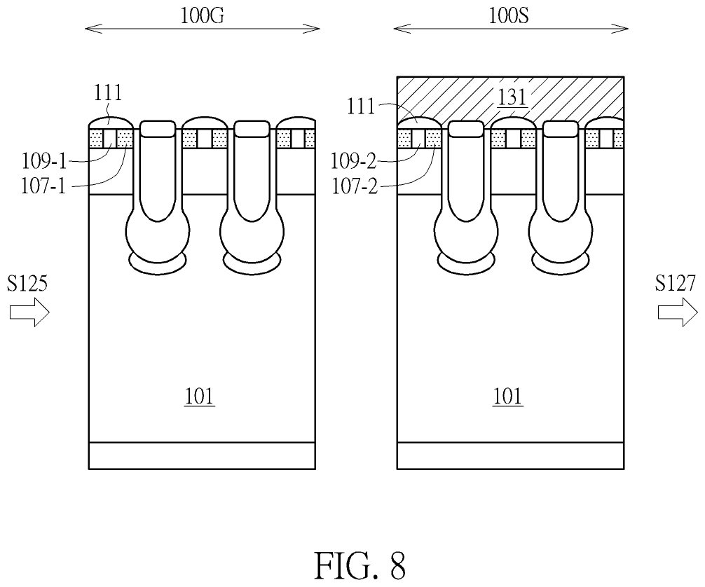

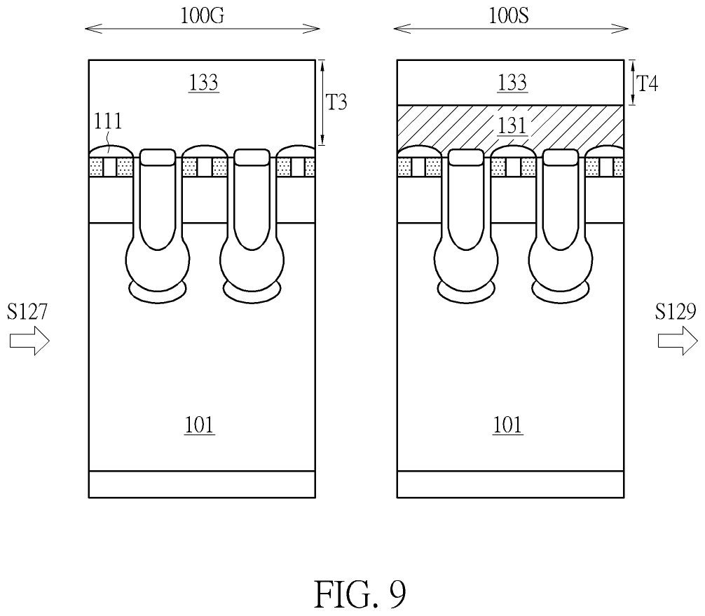

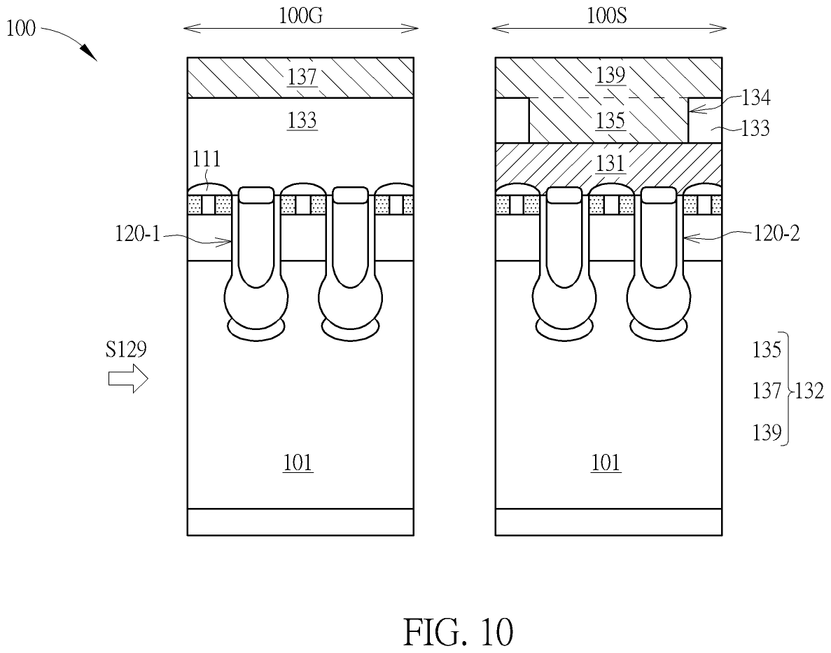

FIG. 3, FIG. 4, FIG. 5, FIG. 6, FIG. 7, FIG. 8, FIG. 9 and FIG. 10 are schematic cross-sectional views of some stages of a method of fabricating a semiconductor device 100 according to an embodiment of the present disclosure. In FIG. 3, FIG. 4, FIG. 5, and FIG. 6, the gate pad region 100G and the source pad region 100S of the semiconductor device 100 have the same cross-sectional structure. In FIG. 7, FIG. 8, FIG. 9 and FIG. 10, the cross-sectional structures in the gate pad region 100G and the source pad region 100S of the semiconductor device 100 are different from each other. Referring to FIG. 3, firstly, a wafer is provided and includes a drain region 103 and a first epitaxial layer 101-1 grown on the drain region 103. In one embodiment, the drain region 103 is, for example, an N-type heavily doped silicon carbide (N⁺ SiC) substrate, and the first epitaxial layer 101-1 is, for example, an N-type silicon carbide epitaxial layer. Then, a shield region 102 such as a P-type heavily doped (P⁺) shield region is formed in the first epitaxial layer 101-1 by an ion implantation process and using a patterned photoresist. The doping concentration of the shield region 102 is, for example, about 1E17 to about 1E19 atoms/cm³, but not limited thereto.

Still referring to FIG. 3, in step S101, a second epitaxial layer 101-2 is grown on the first epitaxial layer 101-1, so that the shield region 102 is buried in an epitaxial layer 101 composed of the first epitaxial layer 101-1 and the second epitaxial layer 101-2. A substrate 110 of the semiconductor device 100 is provided by the drain region 103 and the epitaxial layer 101 formed on the drain region 103. In one embodiment, the second epitaxial layer 101-2 is, for example, an N-type silicon carbide epitaxial layer. The doping concentration of the second epitaxial layer 101-2 may be substantially equal to or higher than that of the first epitaxial layer 101-1. In one embodiment, the doping concentration of the first epitaxial layer 101-1 may be about 1E14 to about 1E16 atoms/cm³, and the doping concentration of the second epitaxial layer 101-2 may be about 1E15 to about 1E17 atoms/cm³, but not limited thereto.

Next, still referring to FIG. 3, in step S103, firstly, a well region 105 such as a P-type well region is formed in the second epitaxial layer 101-2 by an ion implantation process and using a hard mask. Then, a P-type heavily doped (P⁺) region 109 is formed in the well region 105 by another ion implantation process and using another hard mask. The doping concentration of the P-type heavily doped region 109 is higher than that of the well region 105. The P-type heavily doped region 109 is subsequently used as a second doped region 109-1 in the gate pad region 100G and a bulk region 109-2 in the source pad region 100S. Then, an N-type heavily doped (N⁺) region 107 is formed in the well region 105 by another ion implantation process and using another hard mask. The doping concentration of the N-type heavily doped region 107 is higher than that of the well region 105. The N-type heavily doped region 107 abuts the P-type heavily doped region 109. The N-type heavily doped region 107 is subsequently used as a first doped region 107-1 in the gate pad region 100G and a source region 107-2 in the source pad region 100S. Afterwards, a high-temperature activation process is performed to activate the doping ions in the N-type heavily doped region 107 and the P-type heavily doped region 109.

Next, referring to FIG. 4, in step S105, a patterned pad oxide layer 141 and a patterned hard mask 140 are formed on the N-type heavily doped region 107 and the P-type heavily doped region 109 through deposition, photolithography and etching processes. Then, multiple initial trenches 120i are formed in the epitaxial layer 101 by an etching process through the openings of both the patterned pad oxide layer 141 and the patterned hard mask 140. The initial trenches 120i pass through the N-type heavily doped region 107 and the well region 105, and are extended downward, but do not reach the shield region 102. The initial trenches 1201 located in the gate pad region 100G may be referred to as first initial trenches. The initial trenches 120i located in the source pad region 100S may be referred to as second initial trenches. Referring to FIG. 1 and FIG. 4, in the gate pad region 100G, the first doped region 107-1 is located on two sides of the initial trench 120i. The second doped region 109-1 is located between two first doped regions 107-1. In the source pad region 100S, the source region 107-2 is located on two sides of the initial trench 120i. The bulk region 109-2 is located between two source regions 107-2.

Still referring to FIG. 4, in step S107, firstly, a first spacer material layer 142 such as a silicon oxide layer is conformally formed on the sidewalls and the bottom surface of each of the initial trenches 120i by a thermal oxidation process. Then, a second spacer material layer 143 is conformally formed on the sidewalls and the bottom surface of each of the initial trenches 120i by a deposition process to cover the first spacer material layer 142. The second spacer material layer 143 is, for example, a silicon nitride layer. Still referring to FIG. 4, in step S109, a portion of the second spacer material layer 143 and a portion of the first spacer material layer 142 located on the bottom surface of each of the initial trenches 120i are removed by an etching process to expose the bottom surface 120iB of each of the initial trenches 120i, thereby forming a spacer 142S and another spacer 143S located on the sidewalls of each of the initial trenches 120i. In the gate pad region 100G, the spacer 142S located on the sidewalls of the initial trench 120i may be referred to as a first spacer. In the source pad region 100S, the spacer 142S located on the sidewalls of the initial trench 120i may be referred to as a second spacer. Moreover, in the gate pad region 100G, the spacer 143S located on the sidewalls of the initial trench 120i may be referred to as a third spacer. The third spacer, i.e., the spacer 143S covers the first spacer, i.e., the spacer 142S. In the source pad region 100S, the spacer 143S located on the sidewalls of the initial trench 120i may be referred to as a fourth spacer. The fourth spacer, i.e., the spacer 143S covers the second spacer, i.e., the spacer 142S.

Next, referring to FIG. 5, in step S111, a portion of the epitaxial layer 101 directly below the initial trench 120i is removed by an etching process through the exposed bottom surface 120iB of the initial trench 1201 as shown in FIG. 4 to form a sub-trench 120s. The sub-trench 120s is connected with the initial trench 120i, and the bottom surface of the sub-trench 120s is located in the shield region 102. The sub-trench 120s located in the gate pad region 100G may be referred to as a first sub-trench. The sub-trench 120s located in the source pad region 100S may be referred to as a second sub-trench.

Still referring to FIG. 5, in step S113, an oxide layer 145 is formed in the sub-trench 120s by a thermal oxidation process. In the gate pad region 100G, the oxide layer 145 located in the first sub-trench may be referred to as a first oxide layer. In the source pad region 100S, the oxide layer 145 located in the second sub-trench may be referred to as a second oxide layer. During the thermal oxidation process in step S113, the spacer 142S located on the sidewalls of the initial trench 120i is covered by another spacer 143S. Therefore, after the thermal oxidation process, the thickness T2 of the spacer 142S is substantially the same as the thickness T2 of the spacer 142S before the thermal oxidation process. Moreover, the oxide layer 145 formed in the sub-trench 120s may have a thickness T1 by controlling the process parameters of the thermal oxidation process in step S113, such as controlling the amount of inserting oxygen, the heating temperature and the heating time. The thickness T1 of the oxide layer 145 is much greater than the thickness T2 of the spacer 142S. For example, the thickness T1 may be about 10 to 100 times the thickness T2. As shown in FIG. 5, after the step S113, the outline of the first trench 120-1 in the gate pad region 100G and the outline of the second trench 120-2 in the source pad region 100S are formed.

Afterwards, still referring to FIG. 5, in step S115, the hard mask 140 and the spacer 143S located on the sidewalls of both the first trench 120-1 and the second trench 120-2 are removed by a stripping process, such as a wet etching process using a phosphoric acid solution. The spacer 142S on the sidewalls of both the first trench 120-1 and the second trench 120-2 is remained. Moreover, the pad oxide layer 141 on the doped regions located in the well region 105 may also be remained. The spacer 142S, i.e., the first spacer located on the sidewalls of the first trench 120-1 and the oxide layer 145, i.e., the first oxide layer on the bottom surface of the first trench 120-1 constitute a dielectric liner 123 in the first trench 120-1. The spacer 142S, i.e., the second spacer located on the sidewalls of the second trench 120-2 and the oxide layer 145, i.e., the second oxide layer on the bottom surface of the second trench 120-2 constitute a gate dielectric layer 125 in the second trench 120-2.

Next, referring to FIG. 6, in step S117, a conductive material layer is deposited on the pad oxide layer 141 by a deposition process. The conductive material layer fills up the first trench 120-1 and the second trench 120-2. In one embodiment, the composition of the conductive material layer is, for example, doped polysilicon. Then, an etching back process is performed on the conductive material layer to simultaneously form a conductive portion 121 in the first trench 120-1 and a gate electrode 122 in the second trench 120-2. The bottom surface of the conductive portion 121 and the bottom surface of the gate electrode 122 are both lower than the bottom surface of the well region 105. The dielectric liner 123 in the first trench 120-1 surrounds the conductive portion 121. The gate dielectric layer 125 in the second trench 120-2 surrounds the gate electrode 122. In this embodiment, both the lower portion of the conductive portion 121 and the lower portion of the gate electrode 122 that are lower than the bottom surface of the well region 105 may be used as a field plate to distribute the electric field, thereby enhancing the breakdown voltage of the semiconductor device.

Still referring to FIG. 6, in step S119, a dielectric layer 145 is formed on the conductive portion 121 and the gate electrode 122 by a thermal oxidation process. After the dielectric layer 145 is formed, the top surface of the conductive portion 121 and the top surface of the gate electrode 122 may be slightly lower than the top surfaces of the doped regions located in the well region 105. Then, the pad oxide layer 141 on the doped regions located in the well region 105 may be removed by an etching process and using a patterned photoresist to expose the first doped region 107-1 and the second doped region 109-1 in the gate pad region 100G, and to expose the source region 107-2 and the bulk region 109-2 in the source pad region 100S.

Then, still referring to FIG. 6, in step S121, a metal material (not shown) such as titanium (Ti), cobalt (Co), nickel platinum (NiPt) or other suitable metal barrier materials is deposited on the first doped region 107-1, the second doped region 109-1, the source region 107-2 and the bulk region 109-2 by a deposition process. Then, a rapid thermal process (RTP) is performed to make the metal material react with the silicon in the first doped region 107-1, the second doped region 109-1, the source region 107-2 and the bulk region 109-2, thereby forming a silicide layer 111 in the gate pad region 100G and the source pad region 100S. Afterwards, unreacted metal material is removed.

Next, referring to FIG. 7, in step S123, a first metal layer 131 is formed in the gate pad region 100G and the source pad region 100S by a deposition process. The first metal layer 131 covers the silicide layer 111, and also covers the dielectric layer 145 on the conductive portion 121 and the gate electrode 122. In one embodiment, the composition of the first metal layer 131 is, for example, aluminum silicon copper (AlSiCu), but not limited thereto. Using AlSiCu can avoid a junction spike between the first metal layer 131 and the silicon carbide substrate 110.

Then, referring to FIG. 8, in step S125, a patterned photoresist is formed to cover a portion of the first metal layer 131 located in the source pad region 100S. Another portion of the first metal layer 131 located in the gate pad region 100G is remove by an etching process. Therefore, the silicide layer 111 on the first doped region 107-1 and the second doped region 109-1 in the gate pad region 100G is exposed, and the first metal layer 131 located in the source pad region 100S is left. The first metal layer 131 is electrically connected to the silicide layer 111 located on the source region 107-2 and the bulk region 109-2. Removing the first metal layer 131 located in the gate pad region 100G can avoid a parasitic capacitance generated between the first metal layer 131 and a subsequently formed gate pad.

Afterwards, referring to FIG. 9, in step S127, a dielectric material layer is deposited on the gate pad region 100G and the source pad region 100S to cover the silicide layer 111 in the gate pad region 100G and to cover the first metal layer 131 in the source pad region 100S. Then, a chemical mechanical planarization (CMP) process is performed on the dielectric material layer to form a dielectric layer 133. The thickness T3 of a portion of the dielectric layer 133 in the gate pad region 100G is greater than the thickness T4 of another portion of the dielectric layer 133 in the source pad region 100S.

Next, referring to FIG. 10, in step S129, an opening 134 is formed in the dielectric layer 133 of the source pad region 100S by an etching process and using a patterned photoresist to expose the first metal layer 131. Then, a second metal layer 132 is deposited on the dielectric layer 133 and in the opening 134. A via 135 is formed from the portion of the second metal layer 132 filling up the opening 134. In one embodiment, the composition of the second metal layer 132 is, for example, aluminum copper (AlCu), but not limited thereto. Afterwards, the second metal layer 132 on the dielectric layer 133 is patterned by another etching process and using another patterned photoresist, thereby forming a gate pad 137 and a source pad 139 that are laterally separated from each other as shown in FIG. 2 to complete the semiconductor device 100. The gate pad 137 is located directly above the first trench 120-1, and the source pad 139 is located directly above the second trench 120-2. Moreover, the top surface of the gate pad 137 and the top surface of the source pad 139 are on the same plane since the gate pad 137 and the source pad 139 are formed on the flat surface of the dielectric layer 133. In this embodiment, the gate pad 137, the source pad 139 and the via 135 are all formed from the second metal layer 132.

According to some embodiments of the present disclosure, in the semiconductor device, the structure in the gate pad region and the structure in the source pad region may be formed simultaneously in the same process steps. The number of effective trench power transistors is increased directly below the gate pad without additional photo-masks and process steps, thereby improving the electrical performance of the semiconductor device and saving the cost of fabricating the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, having a first surface and a second surface;
a gate pad and a source pad, laterally separated from each other, and both disposed on the first surface of the substrate;
a drain region, disposed on the second surface of the substrate;
a first trench, disposed in the substrate and directly below the gate pad;
a conductive portion, filling up the first trench;
a dielectric liner, disposed in the first trench and surrounding the conductive portion;
a first doped region, located on two sides of the first trench;
a second trench, disposed in the substrate and directly below the source pad;
a gate electrode, filling up the second trench;
a gate dielectric layer, disposed in the second trench and surrounding the gate electrode; and
a source region, located on two sides of the second trench, wherein the first doped region and the source region have the same conductivity type.

2. The semiconductor device of claim 1, wherein the dielectric liner comprises a first portion located on sidewalls of the first trench and a second portion located on a bottom surface of the first trench, the second portion has a thickness greater than a thickness of the first portion, the gate dielectric layer comprises a third portion located on sidewalls of the second trench and a fourth portion located on a bottom surface of the second trench, and the fourth portion has a thickness greater than a thickness of the third portion.

3. The semiconductor device of claim 1, wherein the gate electrode and the conductive portion are both electrically coupled to the gate pad, and the first doped region and the source region are both electrically coupled to the source pad.

4. The semiconductor device of claim 1, wherein the substrate comprises an epitaxial layer located on the drain region, a well region is disposed in the epitaxial layer, the well region is laterally extended from being directly below the gate pad to be directly below the source pad, the first doped region and the source region both have a first conductivity type, the well region has a second conductivity type, the drain region and the epitaxial layer both have the first conductivity type, and the first doped region and the source region are both disposed in the well region.

5. The semiconductor device of claim 4, further comprising a second doped region and a bulk region, both having the second conductivity type and disposed in the well region, wherein the second doped region abuts the first doped region, and the bulk region abuts the source region.

6. The semiconductor device of claim 5, further comprising a silicide layer in contact with top surfaces of the first doped region, the second doped region, the source region and the bulk region.

7. The semiconductor device of claim 6, further comprising a first metal layer disposed directly below the source pad and in contact with the silicide layer, wherein the source pad is electrically connected to the first metal layer, and a vertical projected area of the first metal layer is not overlapped with a vertical projected area of the gate pad.

8. The semiconductor device of claim 7, further comprising a dielectric layer covering the first metal layer and the silicide layer, wherein a portion of the dielectric layer is located directly below the gate pad, another portion of the dielectric layer is located directly below the source pad, and a thickness of the portion of the dielectric layer is greater than a thickness of the another portion of the dielectric layer.

9. The semiconductor device of claim 8, wherein the gate pad and the source pad are composed of a second metal layer, and a top surface of the gate pad and a top surface of the source pad are on the same plane.

10. The semiconductor device of claim 4, further comprising a shield region disposed directly below the first trench and the second trench, and having a conductivity type opposite to the same conductivity type of the first doped region and the source region.

11. A method of fabricating a semiconductor device, comprising:
providing a substrate, comprising forming a drain region and forming an epitaxial layer on the drain region;
performing an ion implantation process on the epitaxial layer to form a first doped region and a source region both having a first conductivity type;
forming a first trench and a second trench in the epitaxial layer, wherein the first trench abuts the first doped region, and the second trench abuts the source region;
forming a dielectric liner in the first trench and a gate dielectric layer in the second trench;
forming a conductive portion in the first trench and a gate electrode in the second trench, wherein the dielectric liner surrounds the conductive portion, and the gate dielectric layer surrounds the gate electrode; and
forming a gate pad and a source pad on the epitaxial layer and laterally separated from each other, wherein the gate pad is located directly above the first trench, and the source pad is located directly above the second trench.

12. The method of claim 11, wherein forming the dielectric liner in the first trench and the gate dielectric layer in the second trench comprises:
forming a first initial trench and a second initial trench in the epitaxial layer;
forming a first spacer on sidewalls of the first initial trench and a second spacer on sidewalls of the second initial trench, and exposing a bottom surface of the first initial trench and a bottom surface of the second initial trench;
removing a portion of the epitaxial layer located directly below the first initial trench and directly below the second initial trench to form a first sub-trench connected to the first initial trench and a second sub-trench connected to the second initial trench; and
performing a thermal oxidation process on the first sub-trench and the second sub-trench to form a first oxide layer and a second oxide layer respectively, wherein the first spacer and the first oxide layer constitute the dielectric liner, and the second spacer and the second oxide layer constitute the gate dielectric layer.

13. The method of claim 12, wherein a thickness of the first oxide layer is greater than a thickness of the first spacer, and a thickness of the second oxide layer is greater than a thickness of the second spacer.

14. The method of claim 12, wherein before forming the first sub-trench and the second sub-trench, further comprising forming a third spacer to cover the first spacer and forming a fourth spacer to cover the second spacer, and after the first oxide layer and the second oxide layer are formed and before forming the conductive portion and the gate electrode, removing the third spacer and the fourth spacer.

15. The method of claim 12, further comprising forming a shield region in the epitaxial layer, wherein the shield region has a second conductivity type, and a bottom surface of the first sub-trench and a bottom surface of the second sub-trench are both located in the shield region.

16. The method of claim 11, further comprising forming a well region in the epitaxial layer, wherein the well region has a second conductivity type, the first doped region and the source region are both formed in the well region, and a bottom surface of the conductive portion and a bottom surface of the gate electrode are both lower than a bottom surface of the well region.

17. The method of claim 16, further comprising forming a second doped region and a bulk region in the well region, wherein the second doped region and the bulk region both have the second conductivity type, the second doped region abuts the first doped region, and the bulk region abuts the source region.

18. The method of claim 17, further comprising depositing a metal material on the first doped region, the second doped region, the source region and the bulk region, wherein the metal material reacts with silicon in the first doped region, the second doped region, the source region and the bulk region to form a silicide layer.

19. The method of claim 18, further comprising:
depositing a first metal layer on the silicide layer;
removing a portion of the first metal layer located in a predetermined region of forming the gate pad;
forming a dielectric layer to cover the first metal layer and the predetermined region of forming the gate pad;
forming an opening in the dielectric layer to expose the first metal layer;
depositing a second metal layer on the dielectric layer and in the opening; and
patterning the second metal layer to form the gate pad and the source pad.

20. The method of claim 19, wherein forming the dielectric layer comprises:
depositing a dielectric material layer on the first metal layer and the predetermined region of forming the gate pad; and
performing a planarization process on the dielectric material layer to form the dielectric layer,
wherein a top surface of the gate pad and a top surface of the source pad formed on the dielectric layer are on the same plane.
